(19) United States
(12) Patent Application Publication
(10) Pub. No.: US 2023/0049438 A1
(43) Pub. Date: Feb. 16, 2023

(54) END-FACE INCIDENT TYPE SEMICONDUCTOR LIGHT RECEIVING DEVICE

(71) Applicant: KYOTO SEMICONDUCTOR CO., LTD., Kyoto (JP)

(72) Inventors: Takatomo ISOMURA, Kyoto (JP); Etsuji OMURA, Kyoto (JP)

(73) Assignee: KYOTO SEMICONDUCTOR CO., LTD., Kyoto (JP)

(21) Appl. No.: 17/979,777

(22) Filed: Nov. 3, 2022

Related U.S. Application Data
(63) Continuation of application No. PCT/JP2020/021628, filed on Jun. 1, 2020.

(51) Int. Cl. H01L 33/10

(52) U.S. Cl. CPC H01L 33/10

(57) ABSTRACT

The end-face incident type semiconductor light receiving device has a first light absorbing region on the main surface side of the semiconductor substrate and causes light incident from the end-face of the semiconductor substrate to enter the first light absorbing region by reflection or refraction, and the first reflective section is provided on the main surface side of the semiconductor substrate to cause light transmitted through the light absorbing region to enter the first light absorbing region, and a single second reflective section is provided on the back surface for causing the light reflected by the first reflective section and transmitted through the first light absorbing region to reflect directly toward the first light absorbing region.

### CROSS-REFERENCE TO RELATED APPLICATION

This application is a continuation application of and claims the priority benefit to PCT Application Serial No. PCT/JP2020/021628 filed Jun. 01, 2020. The entirety of the above-mentioned patent application is hereby incorporated by reference herein and made a part of this specification.

### BACKGROUND

### Technical Field

This invention relates to an end-face incidence type semiconductor light receiving device with enhanced sensitivity to light in the wavelength range called L-band, which is used in optical communication systems.

### Background Art

In the field of optical communications, the amount of optic al signals used in communication systems has been increasing. Developments are being made to increase transmission speed in order to cope with the rapid increase in the volume of communications. In optical communications, optical signals are transmitted from the transmitting side via an optical fiber cable, etc., and at the receiving side, the semiconductor photodetector of the light receiving module converts the received optical signals into electrical signals. It is desirable for the light receiving module to be accurate and easy to align the optical fiber cable and the semiconductor light receiving element, and a plane-mount type light receiving module that can achieve accurate and easy alignment is useful. The plane-mount light receiving module is configured so that the incident light from the optical fiber cable is parallel to the mounting substrate of the semiconductor light receiving device.

As semiconductor light receiving device suitable for plane-mount type light receiving modules, for example, as shown in Patent Documents # 1 and # 2, end-face incident type semiconductor light receiving device are known, which have an optical absorption area on the surface side of the semiconductor substrate and reflected or refracted incident light incident from the end-face of the semiconductor substrate is entered into the light absorption area. The end-face indident type semiconductor light receiving device can be fixed to a mounting substrate without using a sub-substrate for fixing the surface of the semiconductor substrate facing the light incident side, making it easy to manufacture plane-mount type light receiving modules and reducing manufacturing costs.

By the way, optical signals in optical communications have wavelengths between 1530 nm and 1565 nm, called the C-band, which has low loss in optical fiber cables. In recent years, the amount of communication traffic has been increasing. In recent years, in order to cope with increasing communication traffic, light in the wavelength range of 1565 nm to 1625 nm, known as the L-band, has also been used.

Semiconductor light receiving device used for optical communications are often made of compound semiconductors with an InGaAs layer as the light absorption region. The upper limit of the wavelength of the optical signal that can be received based on the band gap energy is about 1670 nm. Therefore, in the L-band, the photosensitivity of semiconductor light receiving device to optical signals tends to decrease as the wavelength approaches 1670 nm (the longer the wavelength). In addition, it is known that, in principle, the lower the temperature in the operating environment, the lower the photosensitivity spectrum shifts to the shorter wavelength side and the lower the photosensitivity in the L-band becomes. Therefore, there is a need to improve the photosensitivity of semiconductor light receiving device.

To improve photosensitivity (light receiving sensitivity), it is effective to thicken the InGaAs layer in the light absorbing region to increase the opportunity to convert optical signals into electrical signals. However, the thicker the optical absorption region, the easier it becomes for crystal defects to occur, and the dark current caused by crystal defects may increase. In addition, the formation of the light absorbing region takes more time and increases the manufacturing cost of the semiconductor light receiving device.

Therefore, for example, in a general surface-incident type light receiving device 100, light transmitted through the light absorbing region 101 is reflected by the reflective portion 102 formed on the backside of the semiconductor substrate and re-entered into the light absorbing area 101. The thickness of the light absorbing area 101 is substantially doubled (see FIG. 13).

However, since incident light spreads out while traveling back and forth between the light absorbing and reflecting areas of the surface-incident type semiconductor light receiving device, it is difficult to sufficiently reintroduce the reflected incident light into the light absorbing area, resulting in a limited improvement in photosensitivity. And surface-incident type semiconductor light receiving device must be fixed to a mounting substrate with the surface facing the incident side using a sub-substrate, making them unsuitable for plane-mount type light receiving device .

On the other hand, the end-face incident type semiconductor light receiving device suitable for plane-mount type light receiving device, such as those in Patents Documents # 1 and # 2, have a structure in which reflected or refracted incident light is once incident on the light absorbing area. Therefore, it is not easy to improve the photosensitivity without increasing the thickness of the optical absorption area.

### PRIOR ART DOCUMENTS

### Patent Documents

Patent Document #1: Japanese Patent No. 3152907. Patent Document #2: Japanese Laid-Open Patent Publication H 11-307806.

### SUMMARY OF THE INVENTION

Thepresent invention is to provide an end-face incident type semiconductor light receiving device with improved photosensitivity.

An end-face incident type semiconductor light receiving device of claim 1 has a first light absorbing region on a main surface side of a semiconductor substrate, wherein light incident from the end-face of the semiconductor substrate is incident on the first light absorbing region by reflection or refraction : comprising , on the main surface side, a first reflective section for causing light transmitted through the first light absorbing region to enter the first light absorbing region, and a single second reflective section for causing the light reflected by the first reflective section and transmitted through the first light absorbing region, and a single second reflective section for causing the light reflected by the first reflective section and transmitted through the first light absorbing region to reflect directly toward the first light absorbing region.

According to the above configuration, light incident from the end-face side of the semiconductor substrate and transmitted through the first light absorbing region on the main surface side is reflected by the first reflective section on the main surface side of the semiconductor substrate and is again incident on the first light absorbing region. Since the first reflective section is on the main surface side where the first light absorbing region is located and these are close to each other, the spread of light traveling back and forth between the first light absorbing region and the first reflectinve section is slight. Therefore, all of the light transmitted through the first light absorbing region can be incident on the first light absorbing region, thereby improving the photosensitivity of the end-face incident type semiconductor light receiving device.

And, light directly reflected by the first reflective section and transmitted through the first light absorbing region can be reflected by the second reflective section and incident on the first light absorbing region. Therefore, since the first and second reflective sections can cause incident light to enter the first light absorbing region a total of four times, the light receiving sensitivity of the end-face incident type semiconductor light receiving device can be improved.

According to the end-face incident type semiconductor light receiving device of the present invention, light receiving sensitivity can be improved.

### BRIEF DESCRIPTION OF THE DRAWINGS

FIG. 1 A cross-sectional view of an essential portion of end-face incident type semiconductor light receiving device according to Embodiment 1 of the present invention;

FIG. 2 Sensitivity spectrum of the end-face incident type semiconductor light receiving device;

FIG. 3 A drawing showing the groove formation process for forming an annular electrode;

FIG. 4 A diagram showing the process of forming an annular electrode;

FIG. 5 A drawing showing the metal film stacking process for forming the first reflective area;

FIG. 6 A diagram showing the process of forming the first reflective sectionthe first;

FIG. 7 A diagram showing the relationship between the Ni film thickness and the reflectance of the first reflective section;

FIG. 8 A cross-sectional view of an essential portion of end-face incident type semiconductor light receiving device according to Embodiment 2;

FIG. 9 A cross-sectional view of an essential portion of end-face incident type semiconductor light receiving device according to Embodiment 3;

FIG. 10 A cross-sectional view of an essential portion of end-face incident type semiconductor light receiving device according to Embodiment 4;

FIG. 11: A cross-sectional view of an essential portion of end-face incident type semiconductor light receiving device according to Embodiment 5;

FIG. 12 A cross-sectional view of an essential portion of end-face incident type semiconductor light receiving device according to Embodiment 6; and

FIG. 13 An illustration of a surface-incident type semiconductor light receiving device.

### DESCRIPTION OF EMBODIMENTS

Best mode for implementing the present invention will now be explained on the basis of embodiments.

### First Embodiment

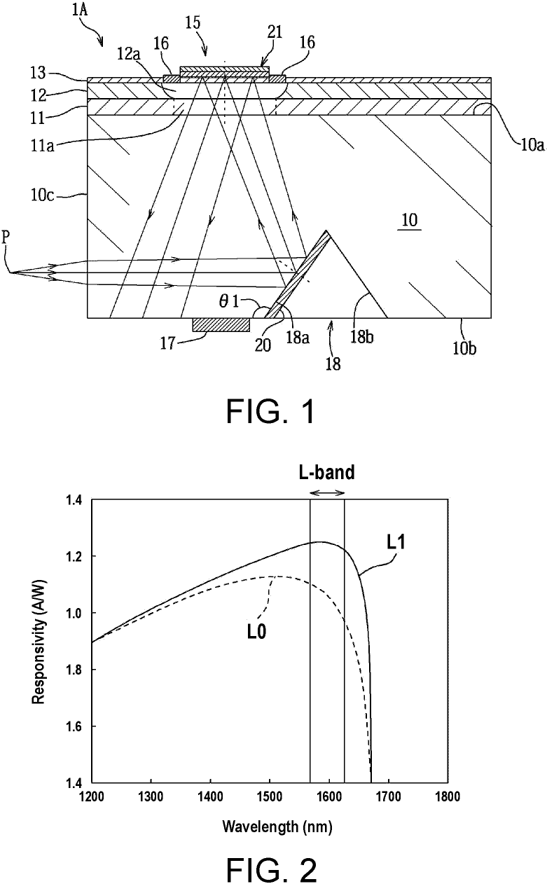

As shown in FIG. 1, in the end-face incident type semiconductor light receiving device 1A, the (100) surface of the semiconductor substrate 10 made of n-InP substrate is the main surface 10a. This semiconductor light receiving device 1A comprises the first light absorbing area 15 ( photodiode ) comprising the light absorbing region 11a in the InGaAs layer 11 formed on the main surface 10a side, and a p-type diffusion region 12a which is formed in the n-InP layer 12 formed on the InGaAs layer 11. The semiconductor substrate 10 is transparent to infrared light with a wavelength longer than 1000 nm. Therefore, infrared light with a wavelength longer than 1000 nm travels in the semiconductor substrate 10.

The p-type diffusion region 12a is formed by doping Zn, for example, in a predetermined region of the n-InP layer 12 on the InGaAs layer 11. Although the figure is omitted, it is formed in a circular shape or a polygonal shape including a rectangle when viewed from the main surface 10a side. The region of the InGaAs layer 11 adjacent to this p-type diffusion region 12a corresponds to the first light absorbing region 11a. On the p-type diffusion area 12a, an annular electrode 16 (p-electrode) is provided to border the p-type diffusion area 12a, i.e., to border the first light absorption area 11a. The junction surface of the annular electrode 16 and the p-type diffusion region 12a has low light reflectance because of the fine irregularities created by alloying. The n-InP layer 12 has a dielectric film 13 in the area other than the first light receiving area 15. The dielectric film 13 is a SiO₂ film, for example.

The semiconductor light receiving device 1A has a back surface 10b of the semiconductor substrate 10 facing the main surface 10a. and is provided with a substrate electrode 17 (n-electrode). One (e.g., substrate electrode 17) of these substrate electrodes 17 or annular electrodes 16 is placed on and connected with a predetermined wiring of a mounting substrate ( not shown in the figure). The other (e.g., annular electrode 16) is connected to the predetermined wiring of the mounting substrate by wire bonding.

The back surface 10b of the semiconductor substrate 10 has a first inclined surface 18a and a second inclined surface 18b, each of which is connected to the back surface 10b at an obtuse angle. The back surface 10b of the semiconductor substrate 10 has a groove 18 (concave portion) formed in an isosceles triangle or trapezoidal shape in cross section by the first and second inclined surfaces 18a and 18b, respectively. Here, the inclined surface of the groove 18 closer to the first light receiving portion 15 is designated as the first inclined surface 18a.

The first inclined surface 18a and the second inclined surface 18b are the {111} plane of the semiconductor substrate 10. The (100) plane and the {111} plane of the semiconductor substrate 10 intersect at an angle of 54.7°. Hence, the first inclined surface 18a continues to the back surface 10b at an obtuse angle of θ1 = 125.3°. This groove 18 is formed by a known etching method using a known etchant with anisotropy that depends on the crystal plane orientation (e.g., a mixture of hydrogen bromide and methanol, which has a slow etching rate for the {111} plane).

The end face 10c perpendicular to the main surface 10a and the back surface 10b of the semiconductor substrate 10 are formed parallel to the direction in which the grooves 18 extend. The light emitted from the optical fiber enters to the end face 10c on the side of the first inclined plane 18a. Let P be the output point. To prevent scattering of the incident light at the end face 10c, the end face 10c is formed smooth. The end face 10c may be provided with an antireflection film, such as a SiN film.

The first inclined surface 18a may be provided with a dielectric film to reflect incident light (e.g., SiN film, a SiO₂ film, etc.) and a metal film (e.g., Ag film, Au film, etc.) to reflect the incident light, and the first inclined surface 18a forms a groove reflective section 20. Here, for example, for an incident light with a wavelength of 1600 nm belonging to the L band, the refractive indices of the n-InP substrate and the SiN film are 3.2 and 2.0, respectively, and the critical angle is about 37.3° according to Snell’s law.

The incident light from the output point P enters the end face 10c and travels parallel to the main face 10a and the back surface 10b. The optical axis of the incident light with respect to the groove reflective section 20 has incident angle of 35.3°, which is close to the critical angle with respect to the groove reflective section 20. Since almost all of the incident light is reflected toward the light receiving area 15. By selecting a dielectric film with a small refractive index or by using the first inclined surface 18a without metal and dielectric films as the groove reflective area 20, the critical angle can also be made small so that the incident light is totally reflected at the groove reflective area 20.

In the vicinity of the first light absorbing area 11a and inside the annular electrode 16 on the p-type diffusion region 12a, the first reflective section 21 is formed. The first reflective section 21 comprises a dielectric film 11 covering the p-type diffusion area 12a and a plurality of metal films stacked on the dielectric film 13. The dielectric film 13 is, for example, a SiO2 film, and the plurality of metal films stacked on the dielectric film 13.

The stacked metal films are a Cr film, a Ni film, a Au film sequentially from the dielectric film. The dielectric film 13 prevents alloying of these metal films and the p-type diffusion area 12a, maintains the smoothness of the interface, and enhances the reflectivity of the first reflective section 21 is increased.

Light emitted from the output point P and incident on the semiconductor substrate 10 from the end surface 10c side is reflected by the groove reflective section 20 toward the light receiving portion 1 15 and incident to the first light absorbing area 11a, and partially converted into an electrical signal. The light transmitted through the first light absorbing area 11a is reflected by the first reflective section 21 near the first light absorbing area 11a, and re-enters the first light absorbing area 11a.

Since the first reflective section 21 is located near the first light absorbing area 11a, the spread of light traveling back and forth between the first light absorbing area 11a and the first reflective area 21 is negligibly small. All light reflected by the first reflective area 21 enters the first light absorbing area 11a. Therefore, since the incident light passes through the light absorbing region 11a twice, the thickness of the first light absorbing area 11a is substantially doubled, and the photosensitivity of the semiconductor light receiving device 1A is improved.

FIG. 2 shows the photosensitivity spectrum of the semiconductor light receiving device 1A with the first reflective section 21 as curve L 1, and the photosensitivity spectrum without the first reflective section 21 is shown by curve L0. The upper limit of the wavelength of the optical signal that can be received is the same at about 1670 nm, but the L-band ( 1565 nm to 1625 nm wavelength range), the first optical absorption area 11a has essentially doubled in thickness due to the first reflective section 21, resulting in improved light receiving sensitivity. Also, for the C-band (wavelength range from 1530 nm to 1565 nm ), the light receiving sensitivity is similarly improved.

Next, the formation method of the first reflective section 21 is described.

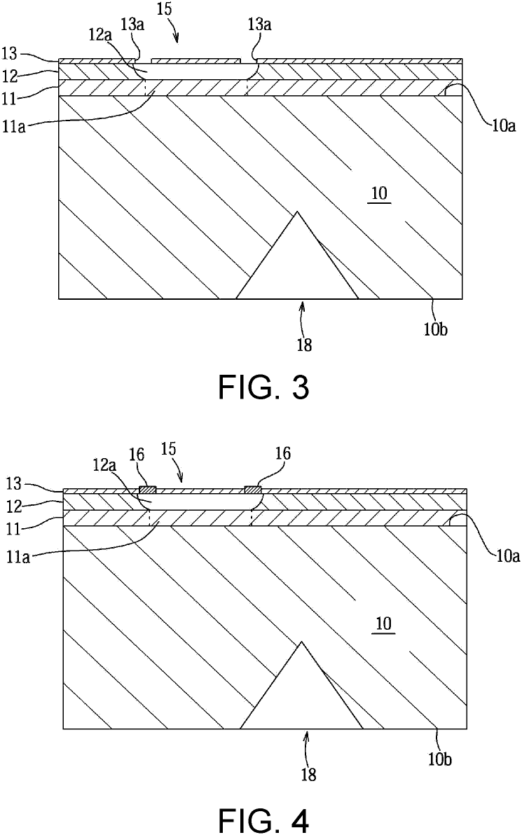

As shown in FIG. 3, a semiconductor substrate with the first light receiving area 15 formed on the main surface 10a side is covered with a dielectric film 13 (e.g., 200 nm thick SiO₂ film). The dielectric film 13 is selectively removed by known photo-etching means, and the annular electrode groove 13a is formed to form the ring electrode 16 (groove formation process). At the bottom of the groove 13a, the p-type diffusion region 12a is exposed.

Next, as shown in FIG. 4, as an adhesion layer with the p-type diffusion region 12a, a metal electrode material having a Cr film and a Ni film, etc., is stacked in the groove 13a, and the metal electrode material outside of the groove 13 is selectively removed by a known photo-etching method to form a ring electrode 16 (ring electrode formation process). For lower resistance, alloying of the junction surface of the p-type diffusion region 12a and the annular electrode 16 may be accelerated by heat treatment. The dielectric film 13 is exposed in the area where the metal electrode material is removed.

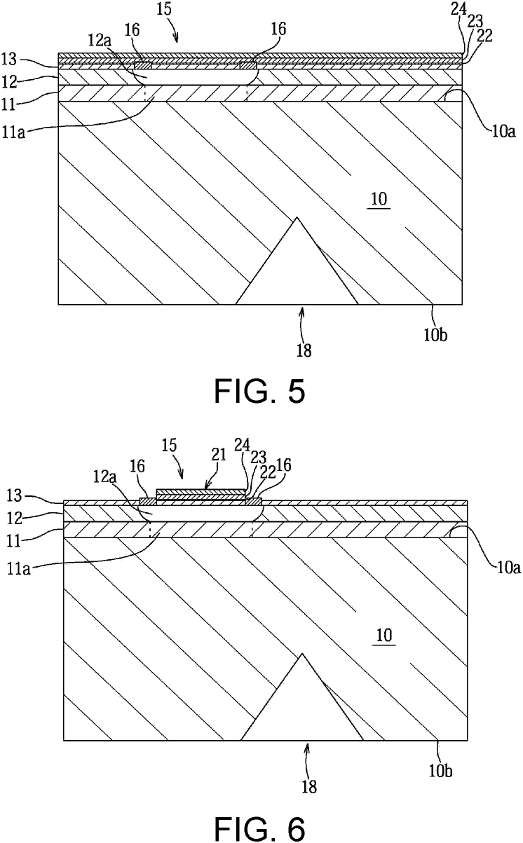

Next, as shown in FIG. 5, the dielectric film 13 and the annular electrode 16 are covered with metal films including a Cr film 22 ( 50 nm thick), a Ni film 23 ( 200 nm thick), and an Au film 24 (200 nm thick), respectively. (metal film stacking process). Then, as shown in FIG. 6, the stacked metal films are selectively removed by known photo-etching methods to form the first reflective section 21 (metal stacking film removal process).

Finally, the groove reflective section 20 is formed and the metal electrode material is selectively deposited on the back surface 10b of the semiconductor substrate 10 to form the substrate electrode 17, thereby the end-face incident type semiconductor light receiving device 1A as shown in FIG. 1 can be obtained. (substrate electrode formation process). The groove 18 may be formed after the formation of the light receiving area 15. It may also be formed after the above metal laminate film removal process.

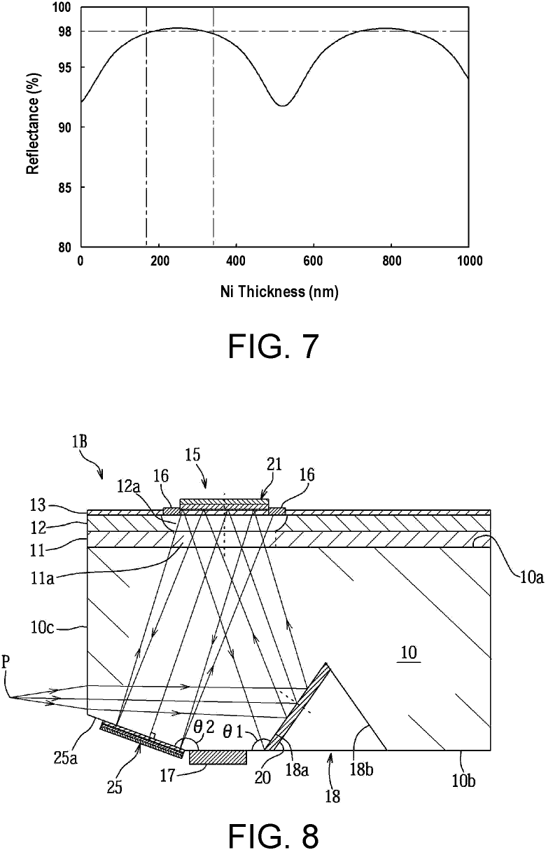

FIG. 7 shows a figure showing the change in reflectance of the first reflective area 21 when the thickness of Ni film 23 is changed, in the case where the dielectric film 13 (SiO₂ film), Cr film 22, and Au film 24 are 200 nm, 50 nm, 200 nm thick, respectively. According to this, the reflectance varies periodically in the range of 92% to 98% depending on the thickness of the Ni film 23. This is due to the mutual interference of reflections at each interface of the multilayer films that make up the first reflective section 21. The thinner the Ni film 23 is, the more advantageous it is to reduce manufacturing cost, by employing a Ni film23 of about 180 nm to 340 nm, a high reflectance of about 98% is formed.

### Second Embodiment

The end-face incident type semiconductor light receiving device 1B of this embodiment is such that the end-face incident type semiconductor light receiving device 1A of Example 1 is transformed to be equipped with a second reflective section 25. As shown in FIG. 8, in the end-face incident type semiconductor light receiving device 1B, the light incident from the output point P on the end face 10c side, is reflected toward the first light receiving area 15 at the groove reflective area 20. The light transmitted through the first light absorbing region 11a is reflected by the first reflecting portion 21 and re-entered into the first light absorbing region 11a. The light transmitted through the first light absorbing region 11a is reflected by the second reflective section 25 and re-entered into the first light absorbing region 11a. The second reflective section 25 is formed on the back side 10b of the semiconductor substrate 10.

The light reflected by the second reflective section 25 enters the first light absorbing region 11a and the light transmitted through the first light absorbing region 11a is reflected by the first reflective section 21 and once more into the first light absorbing region 11a. Therefore, light incident from the end face 10c enters the first light absorbing region 11a a total of four times., which improves the photosensitivity of the semiconductor light receiving device 1B. The light reflected from the second reflective section 25 is spread out and enters the first light absorbing area 11a, the improvement in light receiving sensitivity by the second reflective section 25 may be limited.

When forming the second reflective section 25, by processing the corner portion connecting the back surface 10b to the end surface 10c of the semiconductor substrate 10 to become a flat portion 25a that is connected at a predetermined angle to the back surface 10b and depositing a laminated film with the same structure as the first reflective section 21 on this flat portion 25a. In the case where the first sloping surface 18a is formed to be at an obtuse angle of 125.3° with respect to the back surface 10b, so as to be incident perpendicular to the second reflective portion 25 to improve light receiving sensitivity, the predetermined angle θ2 of the flat portion 25a is set to 160.6°. The flat portion 25a is machined by cutting, grinding, polishing, etc.

### Third Embodiment

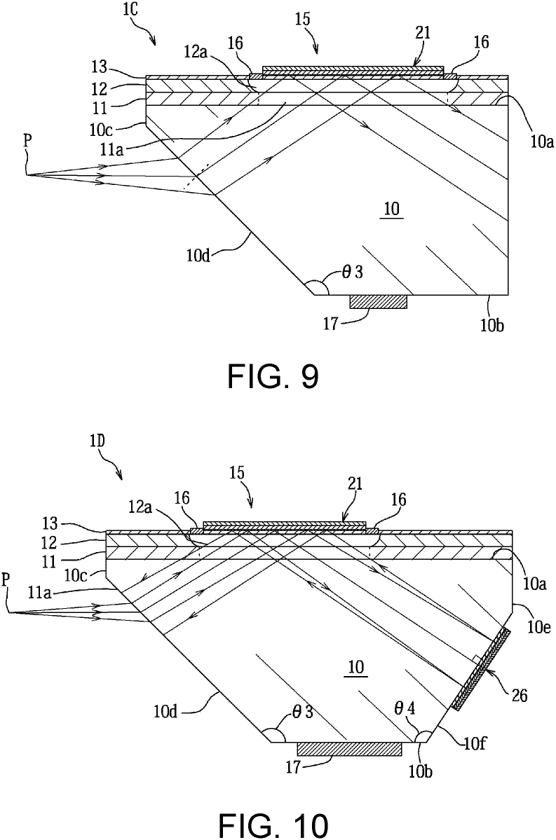

As shown in FIG. 9, in the end- face incident type semiconductor light receiving device 1C, the light incident from the output point P on the end face 10c is refracted by the refractive surface 10d toward the first light receiving area 15. The light transmitted through the first light absorbing area 11a of the first light receiving area 15 is reflected by the first reflective section 21 and then transmitted back to the first light absorbing area 11a. Since the incident light passes through the first light absorbing region 11a twice, the thickness of the first light absorbing region 11a is substantially doubled, and therefore the photosensitivity of the end-face incident type semiconductor light receiving device 1C is improved.

In order to refract the incident light toward the first light receiving area 15, the corner portion of the back surface 10b to the end face 10c is processed to become a flat refracting surface 10d that is connected at a predetermined angle θ 3 to the back surface 10b. The predetermined angle θ3 is, for example, 135°, and the refractive surface 10d is formed by cutting, grinding, polishing, etc. The first reflective section 21 has the same structure as in Embodiments 1,2 above, so the description is omitted.

### Fourth Embodiment

This end-face incident type semiconductor light receiving device 1D is such that the end-face incident type semiconductor light receiving device 1C of Example 3 is transformed and equipped with the second reflective section 26. As shown in FIG. 10, in the end-face incident type semiconductor light receiving device 1D, the light incident from the output point P is refracted by the refracting surface 10d toward the first light receving area 15, the light transmitted through the light absorbing region 11a of the light receiving area 15 is reflected by the first-reflecting part 21, back into the first light absorbing region 11a. The light transmitted through the first light absorbing region 11a is then reflected by the second reflective section 26 formed on the back surface 10b toward the first light receiving portion 15.

The light reflected by the second reflective section 26 enters the first light absorbing region 11a and light transmitted through the first light absorbing region 11a is reflected by the first reflective secion 21 and the light transmitted through the first light absorbing region 11a is reflected by the first reflective section 21 and enters the first light absorbing region 11a one more time. Therefore, since the incident light enters the light absorbing region 11a a total of four times, the photosensitivity of the end-face incident type semiconductor light receiving device 1D is improved. The light reflected by the second reflective section 26 is spread out and enters the first light absorbing area 11a. Since a portion of the light reflected by the second reflective area 26 does not enter the light absorbing area 11a, light receiving sensitivity by the second reflective area 26 may be limited.

The second reflective portion 26 is made on a plane formed on the corner portion from the back surface 10b to the end surface 10e opposite the end surface 10c at a predetermined angle to the back surface 10b. The second reflective portion 26 has the same structure as the first reflective portion 21. The refractive surface 10d is connected to the back surface 10b at an obtuse angle of 03=135° , the predetermined angle θ4 is 147° when the refractive index of the semiconductor substrate 10 relative to air is 3.4. The flat portion 10f is processed by cutting, grinding, polishing, etc.

### Fifth Embodiment

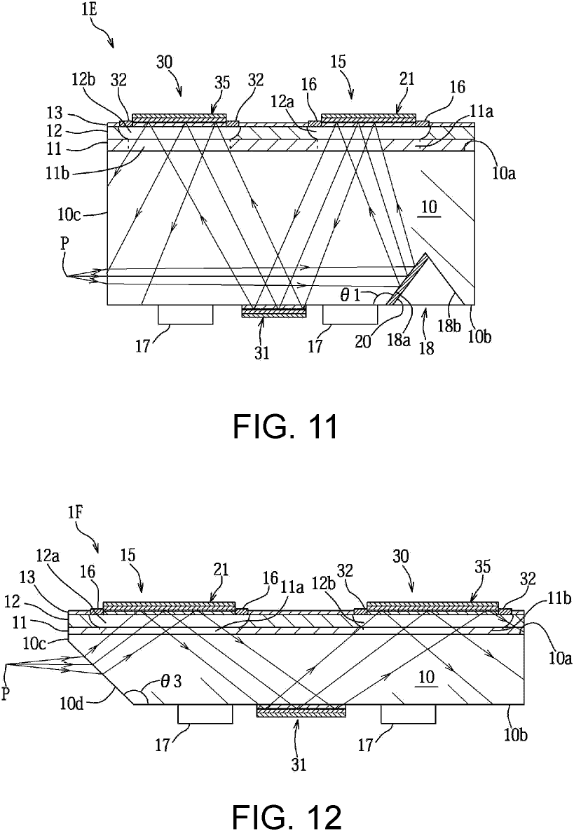

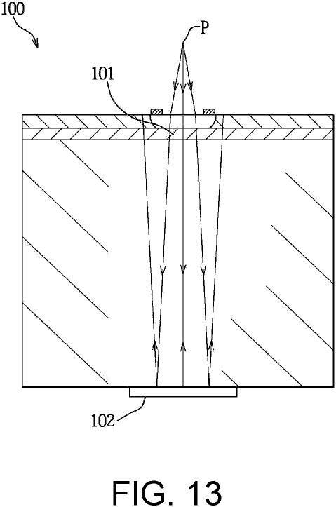

As shown in FIG. 11, the end-face incident type semiconductor light receiving device 1E is such that the end-face incident type semiconductor light receiving device 1A of Embodiment 1 is altered to be provided with a second light receiving area 30 and a third reflective area 31 that reflects light toward the second light receiving area 30.

The semiconductor light receiving device 1E has a first light receiving area 15 and a second light receiving area 30 formed on the main surface 10a side of the semiconductor substrate 10, and the groove reflective area 20 is formed on the back surface 10b side of the semiconductor substrate 10. In addition, a third reflective section is formed on the back surface 10b at a site between the first light receiving area 15 and the second light receiving area 30. The second light receiving area 30 has a second light absorbing region 11b and a p-type diffusion region 12b, and is a photodiode with the same structure as the first light receiving area 15.

In the semiconductor light receiving device 1E, the light incident from the output point P on the end face 10c side is reflected by the reflective section 20 toward the first light receiving area 15, and the light transmitted the first light absorbing region 11a is reflected by the first reflective section 21 to re-enter the first light absorbing region 11a. The light transmitted through the first light absorbing region 11a is then reflected by the third reflecting portion 31 formed on the back surface 10b toward the second light receiving portion 30 and incident on the second light absorbing region 11b of the second light receiving portion 30.

The second light receiving portion 30 has a fourth reflective portion 35 inside the annular electrode 32, and light is incident twice on the second light absorbing region 11b. The third reflective section 31 and the fourth reflective section 35 have the same stacked structure as the first reflective section 21. The fourth reflective section 35 may be omitted.

The light reflected by the third reflective section 31 enters the second light receiving section 30, so that the second light receiving section 30 is separated from the first light receiving area 15, but the first light receiving area 15 and the second light receiving area 30 is electrically connected in parallel and the sum of the outputs of the first and second light receiving areas 15,30 is output from the semiconductor light receiving device 1E. Therefore, the light incident from the end face 10c is transmitted to the first and second light absorbing regions 11a, 11b twice respectively. Thus, the light receiving sensitivity of the semiconductor light receiving device 1E is improved.

The light reflected from the third reflective section 31 spreads and enters the second light absorbing area 11b, since a part of the light reflected by the third reflective area 31 does not enter the second light absorbing area 11b, the improvement in light receiving sensitivity by the third reflective section 31 may be limited. If the fourth reflective section 35 is omitted, the light incident on the second light absorbing region 11b will be only once, and the improvement in light receiving sensitivity by the third reflective section 31 may be limited.

### Sixth Embodiment

As shown in FIG. 12, this end-face incident type semiconductor light receiving device 1F is such that the end-face incident type semiconductor light receiving device 1C of Embodiment 3 is transformed to include a second light receiving area 30 and the third relective section 31. This semiconductor light receiving device 1F has a first light receiving area 15 and a second light receiving area 30 formed apart from the first light receiving area 15 on the main surface 10a side. A third reflective section 31 is provided on the back surface 10b at a site intermediate between the first light receiving portion 15 and the second light receiving portion 30. The second light receving area 30 has a second light absorbing region 11b and a p-type diffusion region 12b, and this second light receiving area 30 is a photodiode with the same structure as the first light receiving area 15.

In the semiconductor light receiving device 1F, the light incident from the output point P is refracted by a refractive surface 10d toward the first light receiving area 15, the light transmitted through the first light absorbing region 11a of the first light receiving part 15 is reflected by the first reflective section 21 and re-entered into the first light absorbing region 11a. The light transmitted through the first light absorbing region 11a is reflected by the third reflective section 31 toward the second light receiving area 30 and re-entered into the second light absorbing region 11b.

The second light receiving part 30 has a fourth reflective section 35 inside the annular electrode 32, and light is incident twice on the second light absorbing region 11b. The third reflective section 31 and the fourth reflective section 35 have the same stacked structure as the first reflective section 15. The fourth reflective section 35 may be omitted.

So as to enter the light reflected by the third reflective section 31 to the second light receiving area 30, the second light receiving area 30 is separated from the first light receiving area 15, but the first light receiving area 15 and the second light receiving area 30 is electrically connected in parallel and the sum of the outputs of the first and second light receiving areas 15, 30 is output from the end-face incident type semiconductor light receiving device 1F. Therefore, the light incident from the output point P enters the first and second light absorbing regions 11a, 11b twice, respectively, and the light receiving sensitivity of the semiconductor light receiving device 1F is improved.

The light reflected by the third reflective section 31 spreads and enters the second light absorbing area 11b, so that a part of the light reflected by the third reflective section 31 does not enter the second light absorbing area 11b, the improvement in light receiving sensitivity by the third reflective section 31 may be limited. If the fourth reflective section 35 is omitted, the light incident on the second light absorbing region 11b will be only once, and the improvement in light receiving sensitivity may be limited more.

The actions and advantages of the above semiconductor light receiving devices 1A to 1F will be described. The semiconductor light receiving devices 1A to 1F have a first light absorbing region 11a on the main surface 10a side of the semiconductor substrate 10 and the light incident from the output point P is incident to the first light absorbing area 11a via rreflectiopn or refraction by groove reflective section 20. The semiconductor light receiving devices 1A to 1F have a first reflective section near the first light absorbing area 11a on the main surface 10a side. The light transmitted through the first light absorbing region 11a is reflected by the first reflective section 21 and re-entered into the first light absorbing region 11a. The light transmitted through the first light absorbing region 11a is reflected by the first reflective section 21 and re-enters the first light absorbing region 11a. Since the first reflective section 21 is in the vicinity of the light absorbing region 11a, the reflected light has a slight spread. Therefore, since all of the light reflected by the first reflective section 21 can be incident on the first light absorbing region 11a, thereby the light receiving sensitivity of the semiconductor light receiving devices 1A to 1F can be improved.

The semiconductor light receiving devices 1B and 1D have a second reflective sections 25, 26. The light reflected by the first reflective section 21 and transmitted through the first light absorbing region 11a can be reflected by the second reflective sections 25, 26 to enter the first light absorbing region 11a. Therefore, since the first and second reflective sections 21, 25, 26 can cause incident light to enter the first light absorbing region 11a a total of four times, the light receiving sensitivity of the semiconductor light receiving devices 1B, 1D can be improved.

The semiconductor light receiving devices 1E and 1F have a second light absorbing region 11b apart from the first light absorbing region 11a on the main surface 10a side and a third reflective section 31 on the back surface 10b. Then, the light reflected by the first reflective section 21 and transmitted through the first light absorbing region 11a is reflected by the third reflective4 section 31 and incident on the second light absorbing region 11b. Therefore, the first reflective section 21 allows the incident light to enter the first light absorbing area 11a twice, and the third reflective section 31 allows the incident light trasmitted through the first light absorbing area 11a to enter the second light absorbing area 11b. The light receiving sensitivity of the semiconductor light receiving devices 1E, 1F can be improved.

The semiconductor light receiving devices 1A-1F have an annular electrode 16 formed on the main surface 10a side of the semiconductor substrate 10 so as to border the first light absorption area 11a. The first reflective section 21 is formed by a dielectric film 13 and a plurality of metal films 22 to 24 stacked inside the annular electrode 16. The interface between the annular electrode 16 and the p-type diffusion region 12a of the first light receiving area 15 a have low reflectivity due to the fine irregularities caused by alloying. However, inside the annular electrode 16, the first reflective section 21 is formed by layering a dielectric film 13 that prevents alloying and maintains the flatness of the interface, and a plurality of metal films 22,23,24 having high reflection ratio. Accordingly, light transmitted through the first light absorbing region 11a is reflected by the first reflective section 21 to enter the first light absorbing region 11a, thereby improving the light receiving sensitivity of the semiconductor light receiving devices 1A to 1F.

The person skilled in the art will embody the present invention by including various alterations.

What is claimed is:

1. An end-face incident type semiconductor light receiving device having a first light absorbing region on a main surface side of a semiconductor substrate, wherein light incident from the end-face of the semiconductor substrate is incident on the first light absorbing region by reflection or refraction; comprising:
a first reflective section, being on the main surface side, for causing light transmitted through the first light absorbing region to enter the first light absorbing region, and
a single second reflective section for causing the light reflected by the first reflective section and transmitted through the first light absorbing region to reflect directly toward the first light absorbing region.

2. The end-face incident type semiconductor light receiving device according to claim 1; the second reflective section reflects the light incident from the first light absorbing region toward the first light absorbing region by the shortest path.
